(19) United States
(12) Patent Application Publication
(10) Pub. No.: US 2008/0003751 A1
(43) Pub. Date: Jan. 3, 2008

(54) Methods for forming dual poly gate of semiconductor device

(75) Inventors: Cheol Hwan Park, Gyeonggi-do (KR); Dong Su Park, Gyeonggi-do (KR); Eun A. Lee, Seoul (KR); Hye Jin Seo, Gyeonggi-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/646,730

(22) Filed: Dec. 28, 2006

(30) Foreign Application Priority Data
Jun. 29, 2006 (KR) 2006-59914

(51) Int. Cl. H01L 21/336

(52) U.S. Cl. 438/283

(57) ABSTRACT

A method for forming a dual poly gate of a semiconductor device includes forming a gate insulating layer on a semiconductor substrate having a first region and a second region; forming an amorphous silicon layer, in which a portion defined by the first region is implanted with impurity ions of a first conductivity type and a portion defined by the second region is implanted with impurity ions of a second conductivity type, on the gate insulating layer; forming silicon seeds on the amorphous silicon layer; forming hemispherical grains on the surface of the amorphous silicon layer using the silicon seeds; and activating the implanted impurity ions and crystallizing the amorphous silicon layer having the hemispherical grains formed thereon by annealing to form a polysilicon layer of a first conductivity type and a polysilicon layer of a second conductivity type in the portions of the amorphous silicon layer defined by the first and second regions, respectively.

### BACKGROUND OF THE INVENTION

1. Field of the Invention

The invention relates to methods for fabricating a semiconductor device, more particularly to methods for forming a dual poly gate of a semiconductor device.

2. Related Technology

Semiconductor devices, such as dynamic random access memory (DRAM) devices, include a cell region and a peripheral circuit region. Particularly, the peripheral circuit region is composed of complementary metal oxide semiconductors (CMOS). In general complementary metal oxide semiconductors, p-type MOS transistors have a buried channel structure. High integration of devices has resulted in a reduction in the length of channels in a buried channel structure, leading to deteriorated leakage current characteristics of the devices due to the application of a high electric field. Dual poly gate structures have been employed to produce p-type MOS transistors having a surface channel structure. Such dual poly gate structures include a p+ poly gate implanted with boron (B) disposed in a region where a p-type MOS transistor is formed and an n+ poly gate implanted with phosphorus (P) disposed in a region where an n-type MOS transistor is formed.

A general method for forming a dual poly gate in a device will be briefly explained below. First, a gate insulating layer is formed on a semiconductor substrate, and a polysilicon layer is formed thereon. Ion implantation is performed using a first photoresist pattern, through which a p-type MOS transistor region is exposed, to implant p-type impurity ions into the polysilicon layer formed within the p-type MOS transistor region. Next, ion implantation is performed using a second photoresist pattern, through which an n-type MOS transistor region is exposed, to implant n-type impurity ions into the polysilicon layer formed within the n-type MOS transistor region. The implantation of the p-type impurity ions may be performed after the implantation of the n-type impurity ions. Annealing is performed on the polysilicon layer to activate the implanted impurity ions, and as a result, a p-type polysilicon layer and an n-type polysilicon layer are formed in place of the polysilicon layer. Impurities, such as a natural oxide layer, present on the p- and n-type polysilicon layers are removed by cleaning using a hydrofluoric acid (HF) solution or a buffered oxide etchant (BOE). For the reduction of resistance, a metal silicide layer, such as a tungsten silicide layer, or a metal layer is formed on the p- and n-type polysilicon layers by deposition. General gate patterning is performed to form the final dual poly gate.

When the impurities are removed by cleaning before formation of the metal silicide layer or the metal layer, the cleaning solution may be infiltrated through grain boundaries of the crystallized p- and n-type polysilicon layers to leave pinholes. Specifically, the mechanism for the formation of pinholes is as follows. Amorphous silicon of the silicon layer is damaged by the high-dose ion implantation processes. When the damaged amorphous silicon is crystallized upon annealing for the activation of the impurity ions, the dopant at a high concentration remains segregated in the grain boundaries. The segregation of the dopant results in poor etching resistance against the cleaning solution, leading to the formation of pinholes. The cleaning solution is infiltrated through the pinholes to damage the gate insulating layer, thus causing degradation in various characteristics of the device.

### SUMMARY OF THE INVENTION

Accordingly, the invention provides a method for forming a dual poly gate of a semiconductor device, the method comprising the steps of: forming a gate insulating layer on a semiconductor substrate having a first region and a second region; forming an amorphous silicon layer, in which a portion defined by the first region is implanted with impurity ions of a first conductivity type and a portion defined by the second region is implanted with impurity ions of a second conductivity type, on the gate insulating layer; forming silicon seeds on the amorphous silicon layer; forming hemispherical grains on the surface of the amorphous silicon layer using the silicon seeds; and activating the implanted impurity ions and crystallizing the amorphous silicon layer having the hemispherical grains formed thereon by annealing to form a polysilicon layer of a first conductivity type and a polysilicon layer of a second conductivity type in the portions of the amorphous silicon layer defined by the first and second regions, respectively.

The method of the invention preferably further comprises the step of cleaning the surface of the amorphous silicon layer. The cleaning step preferably includes the sub-steps of removing the dopant present on the surface of the amorphous silicon layer (‘first cleaning’) and removing a natural oxide layer formed on the amorphous silicon layer (‘second cleaning’). The first cleaning is preferably performed using Standard Cleaning-1 (SC-1) as a cleaning solution and the second cleaning is preferably performed using a HF solution or a BOE as a cleaning solution.

The step of forming an amorphous silicon layer preferably includes the sub-steps of forming an amorphous silicon layer on the gate insulating layer, implanting impurity ions of a first conductivity type into a portion of the amorphous silicon layer defined by the first region using a first mask pattern through which the first region is exposed, and implanting impurity ions of a second conductivity type into a portion of the amorphous silicon layer defined by the second region using a second mask pattern through which the second region is exposed.

The step of forming silicon seeds is preferably carried out within single-type or batch-type equipment.

The step of forming silicon seeds is preferably carried out using a SiH₄ or Si₂H₆ gas as a reaction gas.

The step of forming hemispherical grains is preferably carried out by annealing within a temperature range of 500° C. to 700° C.

The hemispherical grains preferably have a thickness of 20 Å to 700 Å.

The annealing is preferably performed at a temperature of 700° C. to 1,100° C.

According to another aspect, the invention provides a method for forming a dual poly gate of a semiconductor device, the method comprising the steps of: forming a gate insulating layer on a semiconductor substrate having a first region and a second region; forming an amorphous silicon layer, in which a portion defined by the first region is implanted with impurity ions of a first conductivity type and a portion defined by the second region is implanted with impurity ions of a second conductivity type, on the gate insulating layer; forming a silicon layer doped with no impurity (hereinafter, referred to simply as an ‘undoped silicon layer’) on the amorphous silicon layer; forming silicon seeds on the undoped silicon layer; allowing silicon atoms present within the undoped silicon layer to migrate toward the silicon seeds formed on the surface of the undoped silicon layer to form hemispherical grains on the surface of the undoped silicon layer; and crystallizing the undoped silicon layer having the hemispherical grains formed thereon and the amorphous silicon layer while activating the implanted impurity ions by annealing to form a polysilicon layer of a first conductivity type and a polysilicon layer of a second conductivity type in the portions of the amorphous silicon layer defined in the first and second regions, respectively.

The undoped silicon layer preferably has a thickness of several tens of angstroms to two hundred angstroms.

The step of forming an undoped silicon layer is preferably carried out using a SiH₄ or Si₂H₆ gas as a reaction gas.

The method of the invention preferably further comprises the step of cleaning the surface of the amorphous silicon layer. The cleaning step preferably includes the sub-steps of removing the dopant present on the surface of the amorphous silicon layer (‘first cleaning’) and removing a natural oxide layer formed on the amorphous silicon layer (‘second cleaning’). The first cleaning is preferably performed using SC-1 as a cleaning solution and the second cleaning is preferably performed using a HF solution or a BOE as a cleaning solution.

### BRIEF DESCRIPTION OF THE DRAWINGS

FIGS. 1 through 7 are cross-sectional views illustrating a method for forming a dual poly gate of a semiconductor device according to one embodiment of the invention; and

FIG. 8 is a cross-sectional view illustrating a method for forming a dual poly gate of a semiconductor device according to another embodiment of the invention.

### DESCRIPTION OF SPECIFIC EMBODIMENTS

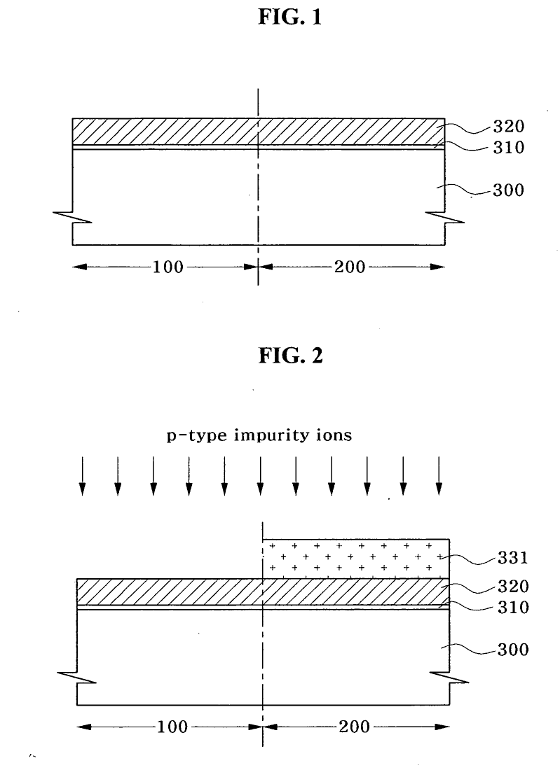

FIGS. 1 through 7 are cross-sectional views illustrating a method for forming a dual poly gate of a semiconductor device according to one embodiment of the invention. With reference to FIG. 1, a gate insulating layer 310 and an amorphous silicon layer 320 are sequentially formed on a semiconductor substrate 300 having a first region 100 and a second region 200. The first region 100 is a region where a p-type MOS transistor is formed, and the second region 200 is a region where an n-type MOS transistor is formed. The gate insulating layer may be in the form of an oxide layer. The amorphous silicon layer 320 may be undoped or doped with an impurity, such as phosphorus (P) or boron (B). If needed, the amorphous silicon layer may have a bilayer structure including an amorphous silicon layer doped with an impurity and an amorphous silicon layer doped with no impurity.

Referring to FIG. 2, a first mask pattern 331, through which the first region 100 is exposed, is formed. The first mask pattern 331 may be a photoresist pattern. As indicated by the arrows shown in FIG. 2, p-type impurity ions, such as boron (B) ions, are implanted using the first mask pattern 331 as an ion implantation barrier layer. As a result, the p-type impurity ions are implanted into the portion of the amorphous silicon layer 320 defined by the first region 100. After completion of the ion implantation, the first mask pattern 331 is removed.

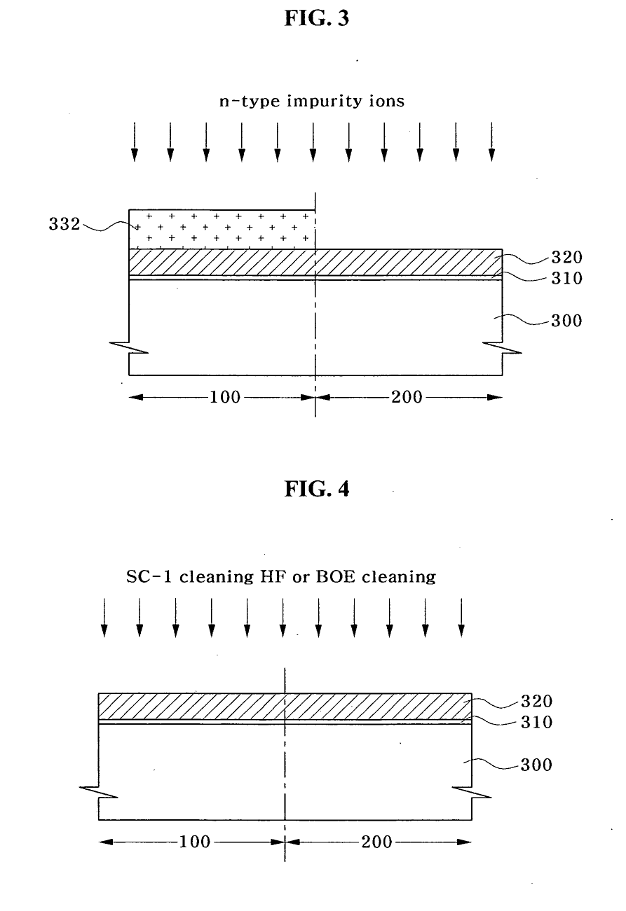

Referring to FIG. 3, a second mask pattern 332, through which the second region 200 is exposed, is formed. The second mask pattern 332 may be a photoresist pattern. As indicated by the arrows shown in FIG. 3, n-type impurity ions, such as phosphorus (P) ions, are implanted using the second mask pattern 332 as an ion implantation barrier layer. As a result, the n-type impurity ions are implanted into the portion of the amorphous silicon layer 320 defined by the second region 200. After completion of the ion implantation, the second mask pattern 332 is removed. Although the implantation of the n-type impurity ions is performed after the implantation of the p-type impurity ions in this embodiment, the order of the implantation processes may be reversed.

Referring to FIG. 4, cleaning is performed on the amorphous silicon layer 320 in which the portion defined by the first region 100 is implanted with the p-type impurity ions and the portion defined by the second region 200 is implanted with the n-type impurity ions. The cleaning involves a two-stage cleaning procedure. First, Standard Cleaning-1 (SC-1) is used as a cleaning solution to remove the impurity ions present on the surface of the amorphous silicon layer 320 (first cleaning). Subsequently, a HF solution or a buffered oxide etchant (BOE) is used as a cleaning solution to remove a natural oxide layer, which may be formed on the surface of the amorphous silicon layer 320. The amorphous silicon layer 320 is cleaned before being crystallized, leaving no pinholes.

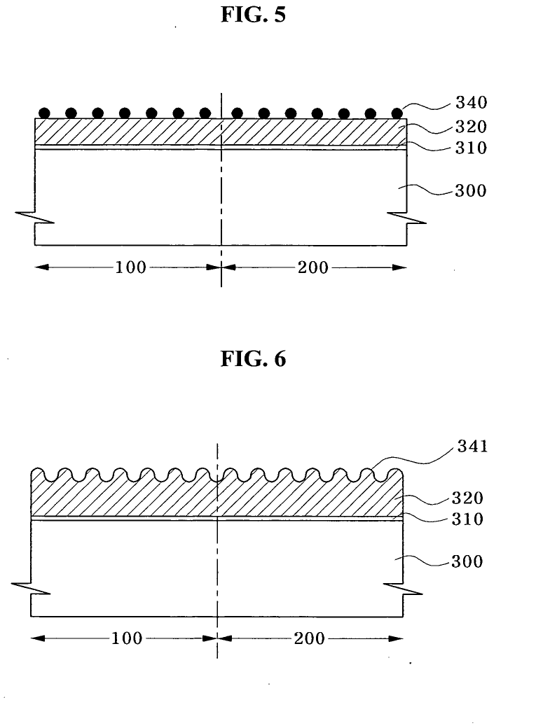

Referring to FIG. 5, silicon seeds (Si-seeds) 340 are formed on the surface of the clean amorphous silicon layer 320. The silicon seeds are formed by the following procedure. First, the semiconductor substrate 300, on which the amorphous silicon layer 320 is formed, is loaded into single-type or batch-type equipment. A silicon source gas is fed into the equipment to form the silicon seeds 340 on the surface of the amorphous silicon layer 320. As the silicon source gas, a SiH₄ or Si₂H₆ gas can be used. The internal pressure of the equipment is adjusted to about 1 mTorr to about 500 mTorr.

Referring to FIG. 6, annealing is performed on the amorphous silicon layer 320 on which the silicon seeds (denoted by 340 in FIG. 5) are formed. This annealing allows silicon atoms present within the amorphous silicon layer 320 to migrate toward the silicon seeds 340 formed on the surface of the amorphous silicon layer 320 to form hemispherical grains 341 on the surface of the amorphous silicon layer 320. The annealing is performed at about 500° C. to about 700° C. and preferably about 600° C. to 650° C. The hemispherical grains 341 are not crystal particles formed by simple crystallization, but silicon crystal particles formed by surface migration of silicon atoms. As a result, the crystal particles become densely packed, thus causing the grain boundaries of the amorphous silicon layer 320 to be close. The thickness of the hemispherical grains 341 is adjusted to about 20 Å to about 700 Å and preferably about 50 Å to 100 Å.

Referring to FIG. 7, the implanted p-type impurity ions and the n-type impurity ions are activated by high-temperature annealing. The high-temperature annealing may be performed in a furnace or equipment for a rapid thermal process (RTP). Regardless of which equipment is used, the annealing is performed at about 700° C. to about 1,100° C. The high-temperature annealing serves to activate the implanted impurity ions, and at same time, to crystallize the silicon of the polysilicon layer. As a result, a p-type polysilicon layer 321 having the hemispherical grains 341 formed thereon is formed in the portion of the amorphous silicon layer 320 defined by the first region 100, and an n-type polysilicon layer 322 having the hemispherical grains 341 formed thereon is formed in the portion of the amorphous silicon layer 320 defined by the second region 200.

Thereafter, cleaning is performed by a common process. Although not shown in FIG. 7, a metal silicide layer (e.g., a tungsten silicide layer or a titanium silicide layer) or a metal layer (e.g., a tungsten layer) is formed on the p-type polysilicon layer 321 and the n-type polysilicon layer 322, and then general gate patterning is performed to form the final dual poly gate. Since the hemispherical grains 341 having close grain boundaries still remain on the surface of the p-type polysilicon layer 321 and the n-type polysilicon layer 322 despite the common cleaning process, the formation of pinholes due to the use of the cleaning solutions is prevented.

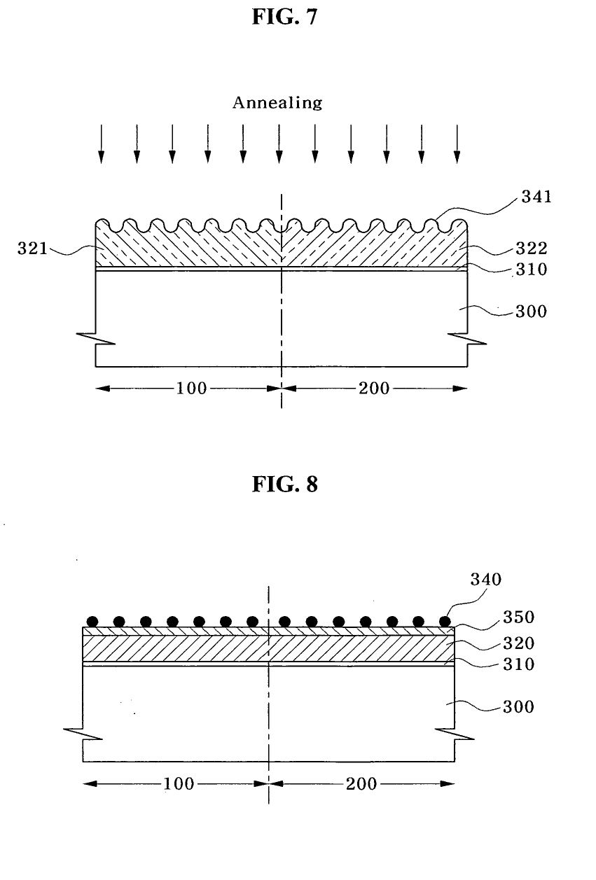

FIG. 8 is a cross-sectional view illustrating a method for forming a dual poly gate of a semiconductor device according to another embodiment of the invention. Reference numerals denoted in FIG. 8 are used for the same elements depicted in FIGS. 1 through 7. Referring to FIG. 8, the method of this embodiment will be explained below. First, the steps explained with reference to FIGS. 1 to 4 are carried out. Next, an undoped silicon layer 350 is formed on the surface of the clean amorphous silicon layer 320. The undoped silicon layer 350 is formed by the following procedure. First, the semiconductor substrate 300, on which the amorphous silicon layer 320 is formed, is loaded into single-type or batch-type equipment. A silicon source gas is fed into the equipment to form the undoped silicon layer 350 on the surface of the amorphous silicon layer 320. As the silicon source gas, a SiH₄ or Si₂H₆ gas is used. The flow of the silicon source gas is optimally adjusted depending on the characteristics of the equipment so that the undoped silicon layer 350 has a thickness of several tens of angstroms to two hundred angstroms.

Subsequently, silicon seeds (Si-seeds) 340 are formed on the undoped silicon layer 350. The silicon seeds are formed by in situ feeding the silicon source gas (e.g., a SiH₄ or Si₂H₆ gas) into the equipment. Next, annealing is performed on the resulting structure on which the silicon seeds 340 are formed. This annealing allows silicon atoms present within the undoped silicon layer 350 to migrate toward the silicon seeds 340 formed on the surface of the undoped silicon layer 350 to form hemispherical grains. The subsequent steps are carried out in the same manner as explained with reference to FIGS. 6 and 7. According to the method, the surface migration of silicon atoms can be maximized because the silicon atoms present in the undoped silicon layer 350 predominantly migrate toward the surface of the undoped silicon layer 350.

What is claimed is:

1. A method for forming a dual poly gate of a semiconductor device, the method comprising the steps of:
forming a gate insulating layer on a semiconductor substrate having a first region and a second region;
forming an amorphous silicon layer, in which a portion defined by the first region is implanted with dopant impurity ions of a first conductivity type and a portion defined by the second region is implanted with dopant impurity ions of a second conductivity type, on the gate insulating layer;
forming silicon seeds on the amorphous silicon layer;
forming hemispherical grains on the surface of the amorphous silicon layer, wherein the hemispherical grains allowing silicon atoms present within the amorphous silicon layer to migrate toward the silicon seeds formed on the surface of the amorphous silicon layer; and
activating the implanted impurity ions and crystallizing the amorphous silicon layer having the hemispherical grains formed thereon by annealing to form a polysilicon layer of a first conductivity type and a polysilicon layer of a second conductivity type in the portions of the amorphous silicon layer defined by the first and second regions, respectively.

2. The method according to claim 1, further comprising the step of cleaning the surface of the amorphous silicon layer.

3. The method according to claim 2, wherein the cleaning step includes the sub-steps of removing the dopant present on the surface of the amorphous silicon layer (first cleaning) and removing a natural oxide layer formed on the amorphous silicon layer (second cleaning).

4. The method according to claim 3, comprising performing the first cleaning using Standard Cleaning-1 (SC-1) as a cleaning solution and the second cleaning is performed using a HF solution or a Buffered Oxide Etchant (BOE) as a cleaning solution.

5. The method according to claim 1, wherein the step of forming an amorphous silicon layer includes the sub-steps of:
forming an amorphous silicon layer on the gate insulating layer;
implanting impurity ions of a first conductivity type into a portion of the amorphous silicon layer defined by the first region using a first mask pattern through which the first region is exposed; and
implanting impurity ions of a second conductivity type into a portion of the amorphous silicon layer defined by the second region using a second mask pattern through which the second region is exposed.

6. The method according to claim 1, comprising carrying out the step of forming silicon seeds is carried out within single-type or batch-type equipment.

7. The method according to claim 1, comprising carrying out the step of forming silicon seeds using a SiH₄ or Si₂H₆ gas as a reaction gas.

8. The method according to claim 1, comprising carrying out the step of forming hemispherical grains by annealing within a temperature range of 500° C. to 700° C.

9. The method according to claim 1, wherein the hemispherical grains have a thickness of 20 Å to 700 Å.

10. The method according to claim 1, comprising performing the annealing at a temperature of 700° C. to 1,100° C.

11. A method for forming a dual poly gate of a semiconductor device, the method comprising the steps of:
forming a gate insulating layer on a semiconductor substrate having a first region and a second region;
forming an amorphous silicon layer, in which a portion defined by the first region is implanted with dopant impurity ions of a first conductivity type and a portion defined by the second region is implanted with dopant impurity ions of a second conductivity type, on the gate insulating layer;
forming an undoped silicon layer on the amorphous silicon layer;
forming silicon seeds on the undoped silicon layer;
forming hemispherical grains on the surface of the amorphous silicon layer, wherein the hemispherical grains allowing silicon atoms present within the amorphous silicon layer to migrate toward the silicon seeds formed on the surface of the amorphous silicon layer; and
crystallizing the undoped silicon layer having the hemispherical grains formed thereon and the amorphous silicon layer while activating the implanted impurity ions by annealing to form a polysilicon layer of a first conductivity type and a polysilicon layer of a second conductivity type in the portions of the amorphous silicon layer defined in the first and second regions, respectively.

12. The method according to claim 11, wherein the undoped silicon layer has a thickness of several tens of angstroms to two hundred angstroms.

13. The method according to claim 11, comprising carrying out the step of forming an undoped silicon layer using a SiH₄ or Si₂H₆ gas as a reaction gas.

14. The method according to claim 11, further comprising the step of cleaning the surface of the amorphous silicon layer.

15. The method according to claim 14, wherein the cleaning step includes the sub-steps of removing the dopant present on the surface of the amorphous silicon layer (first cleaning) and removing a natural oxide layer formed on the amorphous silicon layer (second cleaning).

16. The method according to claim 15, comprising performing the first cleaning using SC-1 as a cleaning solution and the second cleaning is performed using a HF solution or a Buffered Oxide Etchant (BOE) as a cleaning solution.
